(19) United States
(12) Patent Application Publication
(10) Pub. No.: US 2003/0189163 A1
(43) Pub. Date: Oct. 9, 2003

(54) Sensitivity determining method for maintenance of an optical sensor system and sensitivity determining filter therefor

(75) Inventors: Takumi Ueyama, Osaka (JP); Kouji Kusamura, Osaka (JP); Keiichi Tsujimoto, Osaka (JP)

Correspondence Address: Charles F. Wieland III, BURNS, DOANE, SWECKER & MATHIS, L.L.P., P.O. Box 1404, Alexandria, VA, 22313-1404, US

(73) Assignee: Tsubakimoto Chain Co., Japan

(21) Appl. No.: 10/400,518

(22) Filed: Mar. 28, 2003

Related U.S. Application Data
(62) Division of application No. 09/585,628, filed on Jun. 2, 2000, now abandoned.

(30) Foreign Application Priority Data
Jul. 30, 1999 (JP) 11-217934

(51) Int. Cl. H01L 31/00

(52) U.S. Cl. 250/214.1

(57) ABSTRACT

The present invention provides sensitivity determining method for maintenance of an optical sensor system and sensitivity determining filter used therefor. An attenuation filter is disposed in a projected light area between a light projection unit and a light receiving unit of an optical sensor system, and in the case where the light receiving unit receiving a quantity reduced light transmitted through the attenuation filter outputs a signal indicative of light reception, a decision is made such that sensitivity of the optical sensor system is sufficiently high. On the other hand, in the case where the light receiving unit outputs signal indicative of insufficient light reception, a decision is made such that sensitivity of the optical sensor system is poor. In the case where sensitivity of the optical sensor system is poor, it is possible to readily find the cause of the sensitivity being poor, by wiping a light projection surface, a light receiving surface, a reflection surface in succession, or by investigating an offset of the optical axis.

### BACKGROUND OF THE INVENTION

The present invention relates to a sensitivity determining method for maintenance of an optical sensor system, which is used for determining a sensitivity of preexisting optical sensor system, and to a sensitivity determining filter therefor.

At a production site, such as storage shelves of physical distribution warehouse, there is often provided an optical sensor system for detecting objects. The optical sensor system includes a floodlight unit and a light receiving unit receiving light projected from the floodlight unit within a projection light range. The optical sensor system is constructed in a manner such that a detected object blocks off or reflects light projected from the floodlight unit, and thereby, the object is detected.

In the optical sensor system, a quantity of light is reduced due to age deterioration. For this reason, the projection light range (detection distance) becomes shorter over time. A main factor of reducing the quantity of light is due to age deterioration of a light emitting element. Additionally, the optical sensor system is greatly influenced by the environment of the optical sensor system. For example, such environments often include hot and humid environments, environments where dust, oil or the like easily adhere to the optical sensor system. For this reason, in general, when five to ten years elapse after the optical sensor system is put in place, it is necessary to periodically measure sensitivity (quantity of light) of the optical sensor system by using a light quantity meter in order to prevent a malfunction of the optical sensor system.

However, when an optical sensor system is located in a production site, within physical distribution equipment or the like. The projection light range of the optical sensor system is often placed in a limited space. For this reason, it is difficult to place a light quantity meter within the projection light range, and it is difficult to measure a quantity of light impinging on the existing optical sensor system. Therefore, even in the case where the optimal period for carrying out sensitivity measurements of an optical sensor system has gone by, the sensitivity of the optical sensor system is not measured. In other words, the optical sensor system has been often continuously used without performing its maintenance.

As described above, in the case where no maintenance of the optical sensor system is performed, when a production line, physical distribution equipment or the like is operated, the optical sensor system malfunctions, or can not otherwise detect a detection object. In such a case, the aforesaid operation must be stopped for a long time in order to perform maintenance of the optical sensor system. Moreover, when the optical sensor system can not detect a detection object, the whole of optical sensor system is often replaced without investigating the causes of detection failure. In other words, the optical sensor system is replaced without investigating whether a deterioration in a quantity of light of the floodlight unit, dirt on floodlight surface of the floodlight unit or light receiving surface of the light receiving unit, dirt on a reflection surface of a reflecting object; and for an offset of the optical axis by vibration or the like is the cause of the malfunction. For this reason, although the optical sensor system is still sufficiently usable, it has been needlessly replaced with a new optical sensor system.

### BRIEF SUMMARY OF THE INVENTION

The present invention takes the aforesaid problem in the prior art into consideration. It is, therefore, an object of the present invention to dispose an attenuation filter in a projection light range of the optical sensor system, and to receive a light transmitted through the attenuation filter by a light receiving unit, and thereby, to readily determine sensitivity of the optical sensor system.

Further, another object of the present invention is to dispose a plurality of attenuation filters having an equal or different transmittances in a projection light range, and thereby, to more accurately determine sensitivity of the optical sensor system in two stages or more.

Further, another object of the present invention is to dispose an attenuation filter in one or both of a projection side area from a floodlight unit to a reflection object and a reflection side area from the reflection object to the light receiving unit, and thereby, to preferably determine sensitivity of the optical sensor system, even in the case where the optical sensor system is a diffuse reflection type.

Further, the attenuation filter includes a film-like filter main body and a holding frame which is provided on a peripheral edge portion of the filter main body so as to hold the filter main body. With this structure it is possible to readily hold the attenuation filter by one hand, and to preferably dispose it in a projection light range by one hand even in the case where the surroundings of the projection light range is very narrow, and thus, to readily perform a maintenance of the optical sensor system.

In order to achieve the above objects, the present invention provides a first sensitivity determining method comprising the following steps of: disposing an attenuation filter in a projection light range of an optical sensor system including a light receiving unit which receives a light projected from a floodlight unit via the projection light range; receiving a transmitted light through the attenuation filter by the light receiving unit; and determining sensitivity of the optical sensor system on the basis of the light receiving result of the light receiving unit.

According to the first sensitivity determining method, after confirming that the optical sensor system is in a state of being operated, the attenuation filter is disposed in the projection light range of the optical sensor system, and thereby, a light projected from the floodlight unit transmits the attenuation filter, and then, is reduced in quantity at a predetermined transmittance. The transmitted light thus reduced is received by the light receiving unit; therefore, it is possible to readily determine sensitivity of the optical sensor system on the basis of the light receiving result of the light receiving unit. The determination of sensitivity is carried out in the following manner. For example, in the case where the light receiving unit receiving the transmitted light outputs a light receiving signal, the sensitivity of the optical sensor system is sufficiently high; on the other hand, in the case where the light receiving unit outputs no light receiving signal, the sensitivity of the optical sensor system is determined to be poor.

As described above, it is possible to readily determine sensitivity of the optical sensor system; therefore, in the case where the sensitivity of the optical sensor system is poor, the cause can be readily found in the following manner. For example, after wiping a floodlight surface of the floodlight unit, a light receiving surface of the light receiving unit and a reflection surface of a reflection object, sensitivity determination is again made by the attenuation filter. In the case where the sensitivity is determined to be poor, after investigating an offset of the optical axis, the sensitivity determination is again made by the attenuation filter. Further, in the case where the sensitivity is determined to be poor, the floodlight unit and/or the light receiving unit are replaced with a new unit, and thus, maintenance is performed. Therefore, it is possible to avoid the optical sensor system being replaced with a new optical sensor system at a stage that the optical sensor system is still sufficiently usable.

Further, the present invention provides a second sensitivity determining method wherein a plurality of attenuation filters having an equal or different transmittances are successively disposed in a projection light range of an existing optical sensor system, and each time the number of disposed attenuation filters increases, or each time the arranged attenuation filter is replaced with a new one, sensitivity of the optical sensor system is determined on the basis of the light receiving result of the light receiving unit.

According to the second sensitivity determining method, in the case of using the plurality of attenuation filters having an equal or different transmittances, one of these attenuation filters is disposed in a projection light range of the optical sensor system, and thereby, a projected light transmits through the attenuation filter, and then, the transmitted light thus reduced in quantity is received by the light receiving unit. In the case where the light receiving unit outputs a light receiving signal, a decision is made such that the sensitivity of the optical sensor system is sufficiently high; on the other hand, in the case where the light receiving unit outputs no light receiving signal, a decision is made such that the sensitivity of the optical sensor system is poor.

In the case where the sensitivity of the optical sensor system is sufficiently high, still another attenuation filter is disposed in the projection light range, and thereby, a plurality of attenuation filters are disposed therein. By doing so, a light projected from the floodlight unit transmits the plurality of attenuation filters, and then, is reduced in quantity at a magnification according to the number of these attenuation filters. The transmitted light thus reduced is received by the light receiving unit, and then, in the case where the light receiving unit outputs a light receiving signal, a decision is made such that the sensitivity of the optical sensor system is sufficiently high; on the other hand, in the case where the light receiving unit outputs no light receiving signal, a decision is made such that the sensitivity of the optical sensor system is nearby poor.

In the above manner, the sensitivity of the optical sensor system is determined in plural stages; therefore, it is possible to more accurately determine the sensitivity of the optical sensor system.

In the case of using a plurality of attenuation filters having different transmittances, an attenuation filter having a higher transmittance is disposed in a projection light range of the optical sensor system, and thereby, a projection light transmits the attenuation filter, and then, the transmitted light thus reduced is received by the light receiving unit. In the case where the light receiving unit outputs a light receiving signal, a decision is made such that the sensitivity of the optical sensor system is sufficiently high; on the other hand, in the case where the light receiving unit outputs no light receiving signal, a decision is made such that the sensitivity of the optical sensor system is poor.

In the case where the sensitivity of the optical sensor system is sufficiently high when using the attenuation filter having a higher transmittance, in place of the attenuation filter having a higher transmittance, an attenuation filter having a lower transmittance is disposed in the projection light range, and thereby, a projection light transmits the attenuation filter, and then, the transmitted light thus reduced is received by the light receiving unit. In the case where the light receiving unit outputs a light receiving signal, a decision is made such that the sensitivity of the optical sensor system is sufficiently high; on the other hand, in the case where the light receiving unit outputs no light receiving signal, a decision is made such that the sensitivity of the optical sensor system is nearby poor. In the above manner, the sensitivity of the optical sensor system is determined in plural stages; therefore, it is possible to more accurately determine the sensitivity of the optical sensor system.

Further, the present invention provides a third sensitivity determining method wherein the attenuation filter is disposed in one or both of a projection side area from the floodlight unit of the existing optical sensor system having the floodlight unit and the light receiving unit, which are integrally provided, to a reflection object, and a reflection side area from the reflection object to the light receiving unit.

According to the third sensitivity determining method, the attenuation filter is disposed in one of a projection side area from the floodlight unit to a reflection object and a reflection side area from the reflection object to the light receiving unit, and thereby, a projection light projected from the floodlight unit once transmits the attenuation filter, and then, is reduced in quantity at a predetermined transmittance. The transmitted light thus reduced is received by the light receiving unit; therefore, it is possible to determine the sensitivity of the optical sensor system on the basis of the light receiving result of the light receiving unit in the same manner as the above first sensitivity determining method.

In addition, the attenuation filter is disposed in both of the projection side area and the reflection side area, and thereby, a projection light projected from the floodlight unit transmits the attenuation filter, and then, is reduced at a predetermined transmittance. The transmitted light thus reduced is reflected by the reflection object, and then the reflected light again transmits the attenuation filter, and is further reduced in quantity at a predetermined transmittance. The transmitted light thus reduced is received by the light receiving unit; therefore, it is possible to determine the sensitivity of the optical sensor system on the basis of the light receiving result of the light receiving unit in the same manner as the above second sensitivity determining method.

Moreover, in order to achieve the above objects, the present invention provides a sensitivity determining filter for maintenance of an optical sensor system, comprising: a film-like filter main body which reduces a projection light in quantity generated by an optical sensor system including a light receiving unit receiving the light projected from a floodlight unit; and a holding frame which is provided on a peripheral edge portion of the filter main body so as to hold the filter main body.

According to the present invention, there is provided a small-size film-like filter main body having a dimension capable of transmitting a projected light. Therefore, it is possible to readily hold the film-like filter main body by one hand, and to preferably dispose it in the projection light range by one hand even in the case where the surroundings of the projection light range is very narrow, and thus, to readily determine sensitivity of an optical sensor system. In addition, the determination of sensitivity is readily carried out; therefore, it is possible to readily find the causes of the case where the sensitivity of the optical sensor system is poor.

The above and further objects and features of the invention will more fully be apparent from the following detailed description with the accompanying drawings.

### BRIEF DESCRIPTION OF THE SEVERAL VIEWS OF THE DRAWINGS

FIG. 1 is a perspective view showing a construction of sensitivity determining filter according to the present invention;

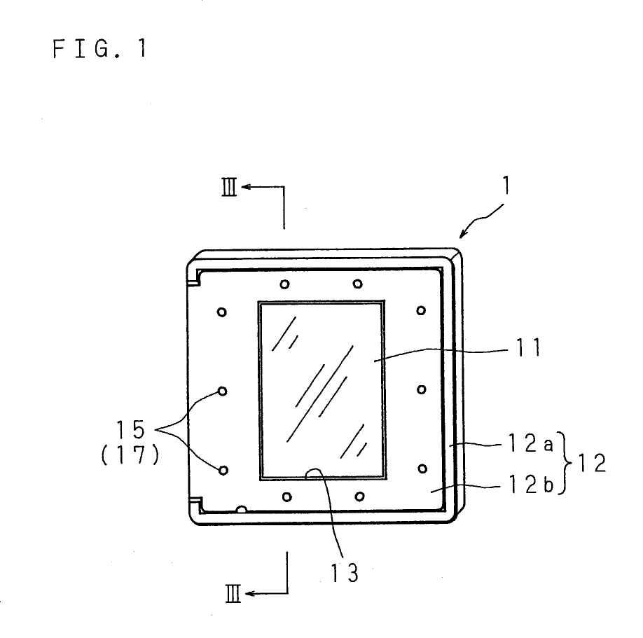

FIG. 2 is a perspective view showing a construction of the sensitivity determining filter according to the present invention which is in a state of being opened;

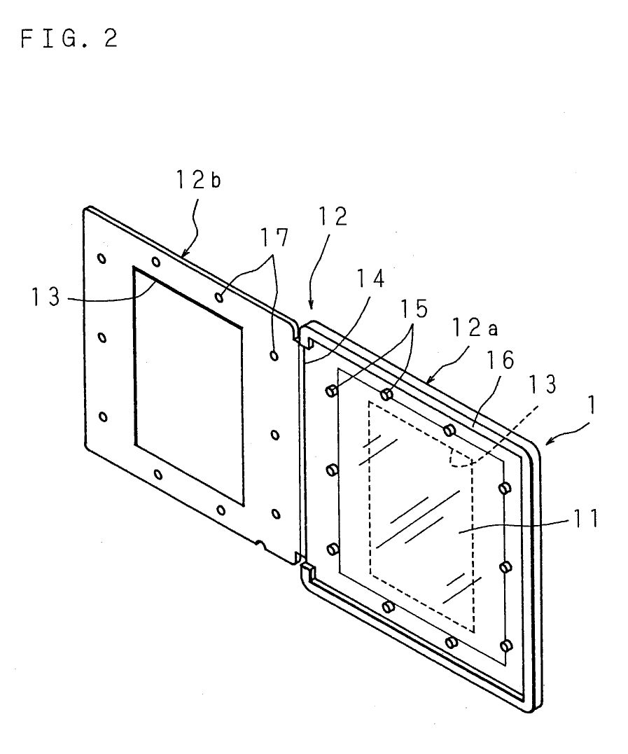

FIG. 3 is an enlarged sectional view taken along a line III-III of FIG. 1;

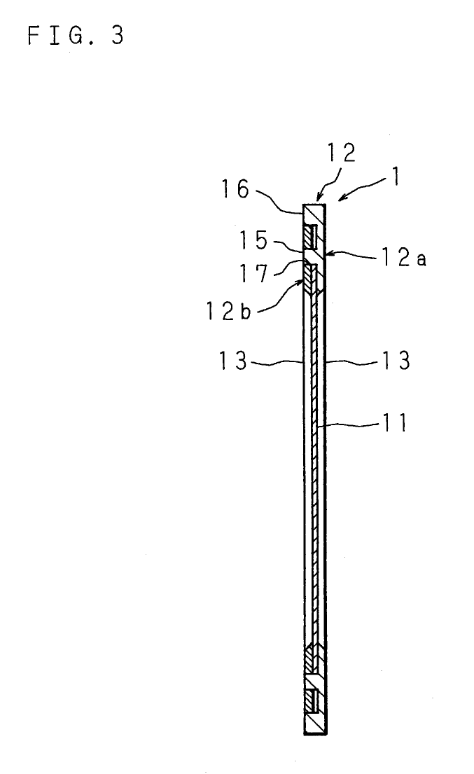

FIG. 4 is an exploded perspective view showing a construction of the sensitivity determining filter according to the present invention;

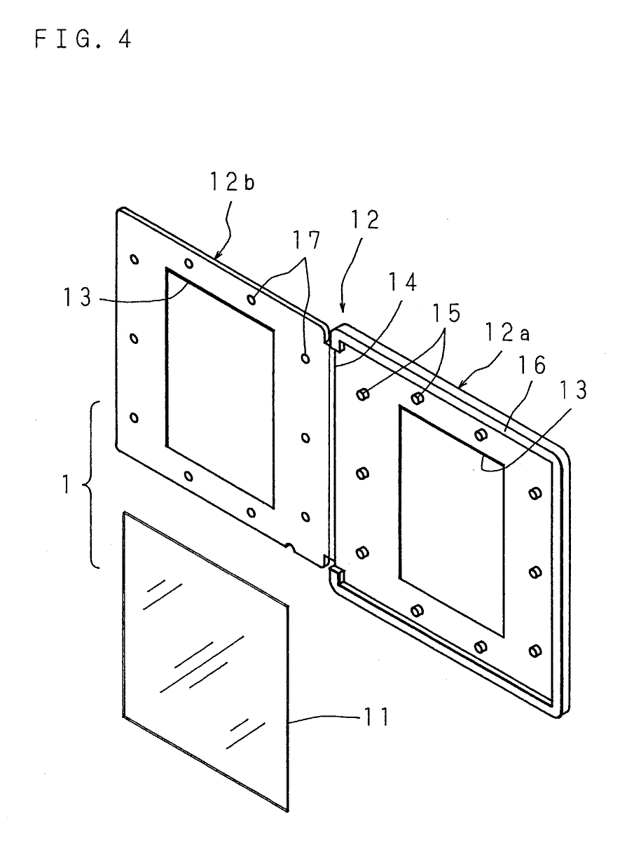

FIG. 5 is a schematic view showing the case where the sensitivity determining filter is used in an existing optical sensor system which is transmission type;

FIG. 6 is a schematic view showing the case where the sensitivity determining filter is used in an existing optical sensor system which is diffuse reflection type;

FIG. 7 is an exploded perspective view showing another construction of the sensitivity determining filter; and

FIG. 8 is an exploded perspective view showing still another construction of the sensitivity determining filter.

### DETAILED DESCRIPTION OF THE INVENTION

The sensitivity determining filter comprises an attenuation filter 1. The attenuation filter 1 includes square film-like filter main body 11, and a flat holding frame 12 for holding the filter main body 11. The filter main body 11 reduces a projected light in quantity generated by an existing optical sensor system 2 including a light receiving unit 22 for receiving a light projected from a floodlight unit 21.

The filter main body 11 is a synthetic resin film having a thickness of about 0.05 mm, and there are two kinds of filters; more specifically, one filter has a transmittance of about 80% of a projected light having a wavelength of 600 nm to 720 nm, and the other filter has a transmittance of about 63% of the same.

The holding frame 12 includes a pair of frame main bodies 12a and 12b which are individually formed with square openings 13 each having a dimension smaller than the filter main body 11. The peripheral edge portion of the filter main body 11 is sandwiched between these frame main bodies 12a and 12b. The pair of frame main bodies 12a and 12b are coupled by a thin hinge 14. One frame main body 12a is provided with a plurality of positioning protrusions 15 which are formed around the opening 13, and positions the filter main body 11 with respect to the opening 13, and a projecting portion 16 formed along its outer peripheral edge. Moreover, the other frame main body 12b is formed with a plurality of holes 17 into which the positioning protrusions 15 are fitted, at the position corresponding to these protrusions 15.

The filter main body 11 is held in the following manner. More specifically, in a state that the pair of frame main bodies 12a and 12b are opened, the peripheral edge portion of the filter main body 11 is placed around the opening 13 of one frame main body 12a, and then, at least one side of the peripheral edge portion of the filter main body 11 is abutted against the positioning protrusions 15 so that the filter main body 11 is positioned with respect to the opening 13. Subsequently, the other frame main body 12b is closed using the hinge 14 as a fulcrum so that the positioning protrusions 15 are fitted into the holes 17, and thereby, the peripheral edge portion of the filter main body 11 is sandwiched between the frame main bodies 12a and 12b, and simultaneously, these frame main bodies 12a and 12b are mutually combined.

Next, the following is a description on sensitivity determining method for maintenance of an optical sensor system 2 using the sensitivity determining filter having the construction as described above.

[Determining Method 1]

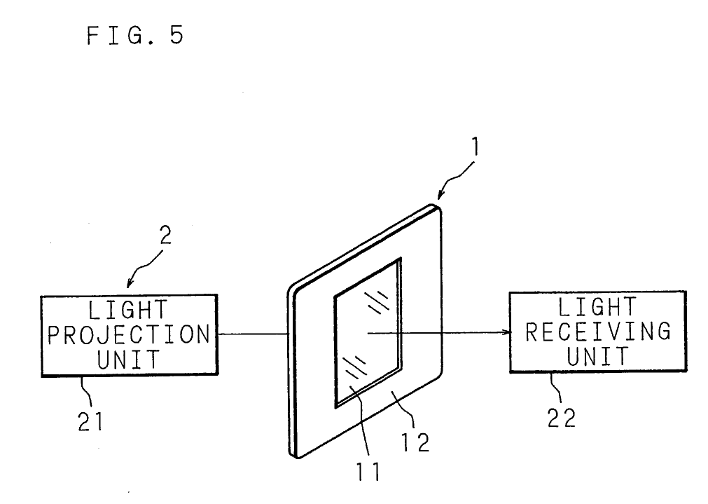

In the case where the optical sensor system 2, located in a production site, physical distribution equipment or the like, is a transmission type (see FIG. 5), for example, only one attenuation filter 1 having a transmittance of 80% is used. Then, after confirming that the optical sensor system 2 is in a state of being operated, the above attenuation filter 1 is disposed in a projection light range of the optical sensor system 2. Thereby, light projected from the floodlight unit 21 transmits through the attenuation filter 1, and then, is reduced in quantity at a transmittance of 80%. The transmitted light thus reduced is received by the light receiving unit 22. After the light receiving unit 22 receives the transmitted light, in the case where the light receiving unit 22 outputs a light receiving signal, the sensitivity of the optical sensor system 2 is still sufficiently high; therefore, a decision is made such that no maintenance of the optical sensor system is required. On the other hand, in the case where the light receiving unit 22 outputs no light receiving signal, the sensitivity of the optical sensor system 2 is poor; therefore, a decision is made such that a maintenance of the optical sensor system is required.

As described above, in the case where a decision is made such that the sensitivity of the optical sensor system is poor, the causes are investigated. The causes are investigated in the following manner. For instance, after wiping a floodlight surface of the floodlight unit 21 and a light receiving surface of the light receiving unit 22, sensitivity determination is again made by the attenuation filter 1. In the case where the sensitivity determination is poor, after investigating an offset of the optical axis of the floodlight unit 21 and the light receiving unit 22, the sensitivity determination is again made by the attenuation filter 1. Further, in the case where the sensitivity determination is poor, the floodlight unit 21 or the light receiving unit 22 are replaced with a new unit. Therefore, it is possible to avoid the optical sensor system 2 from being replaced with a new optical sensor system in a stage that the optical sensor system 2 is still sufficiently usable.

[Determining Method 2]

In this determining method 2, the attenuation filter 1 having a transmittance of 80% used in the above determining method 1 is used by with another attenuation filter for example. As described above, in the case where the optical sensor system 2 located is a transmission type (see FIG. 5), after confirming that the optical sensor system 2 is in a state of being operated, one attenuation filter 1 is disposed in a projection light range of the optical sensor system 2, and thereby, a light projected from the floodlight unit 21 transmits through the attenuation filter 1, and then, is reduced in quantity at a transmittance of 80%. Thus, a decision is made in the same manner as the above determining method 1.

In the case where the sensitivity is sufficiently high, two (plural) attenuation filters 1 and 1 are disposed in the projection light range, and thereby, a light projected from the floodlight unit 21 transmits through the two attenuation filters 1 and 1, and then, is reduced in quantity at a transmittance of 64% by a magnification of the number of attenuation filters 1 and 1. The transmitted light thus reduced is received by the light receiving unit 22, and then, in the case where the light receiving unit 22 outputs a light receiving signal, a decision is made such that the sensitivity of the optical sensor system 2 is sufficiently high. On the other hand, in the case where the light receiving unit 22 outputs no light receiving signal, a decision is made such that the sensitivity of the optical sensor system 2 is nearly bad.

As described above, the sensitivity determination is made in two stages; therefore, it is possible to more accurately carry out the sensitivity determination as compared with the above determination method 1. In the case where a decision is made such that the sensitivity is poor, the causes are investigated in the same manner as described in the above determination method 1.

[Determination Method 3]

In this determining method 3, one attenuation filter having a transmittance of 80% and one attenuation filter having a transmittance of 63% (plural in total) are used. As described above, in the case where the optical sensor system 2 located is transmission type, after confirming that the optical sensor system 2 is in a state of being operated. The attenuation filter having a transmittance of 80% is disposed in a projection light range of the optical sensor system 2, and thereby, a light projected from the floodlight unit 21 transmits through the attenuation filter, and then, is reduced in quantity at a transmittance of 80%. Thus, a decision is made in the same manner as the above determining method 1.

In the case where the sensitivity is sufficiently high, the attenuation filter having a transmittance of 80% is removed from the projection light range, and then, the attenuation filter having a transmittance of 63% is disposed in a projection light range of the optical sensor system 2, and thereby, a light projected from the floodlight unit 21 transmits the attenuation filters, and then, is reduced in quantity at a transmittance of 63%. The transmitted light thus reduced is received by the light receiving unit 22, and then, in the case where the light receiving unit 22 outputs a light receiving signal, a decision is made such that the sensitivity of the optical sensor system 2 is sufficiently high. On the other hand, in the case where the light receiving unit 22 outputs no light receiving signal, a decision is made such that the sensitivity of the optical sensor system 2 is nearby poor.

As described above, the sensitivity determination is made in two stages; therefore, it is possible to more accurately carry out the sensitivity determination as compared with the above determination method 1. In the case where a decision is made such that the sensitivity is poor, the causes are investigated in the same manner as described in the above determination method 1.

[Determination Method 4]

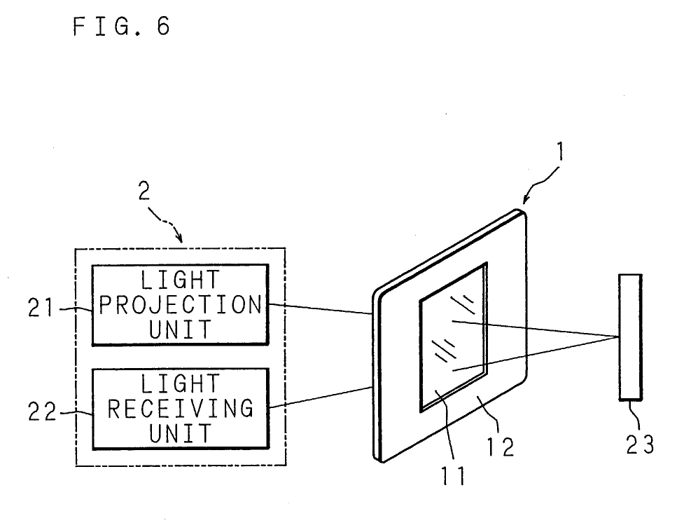

FIG. 6 is a schematic view showing the case where the sensitivity determining filter is used in an existing optical sensor system 2 which is diffuse reflection type.

For instance, in the case where an optical sensor system 2 already provided in a production site, a physical distribution equipment or the like, is diffuse reflection type, the attenuation filters used in the above determining methods 1 to 3 are disposed in one of a projection side area from a floodlight unit to a reflection object 23 and a reflection side area from the reflection object 23 to the light receiving unit, and then, a decision is made in the same manner as the above determining methods 1 to 3. Moreover, the attenuation filters used in the above determining methods 1 to 3 are arranged in both of the projection side area and the reflection side area, and then, a decision is made in the same manner as the above determining methods 1 to 3. In the case where a decision is made such that the sensitivity is poor, the causes are investigated in the same manner as described in the above determination method 1.

In the above embodiment, in the case of using a plurality of attenuation filters having an equal or different transmittances, the number of attenuation filters is not specially limited so long as they are used two or more.

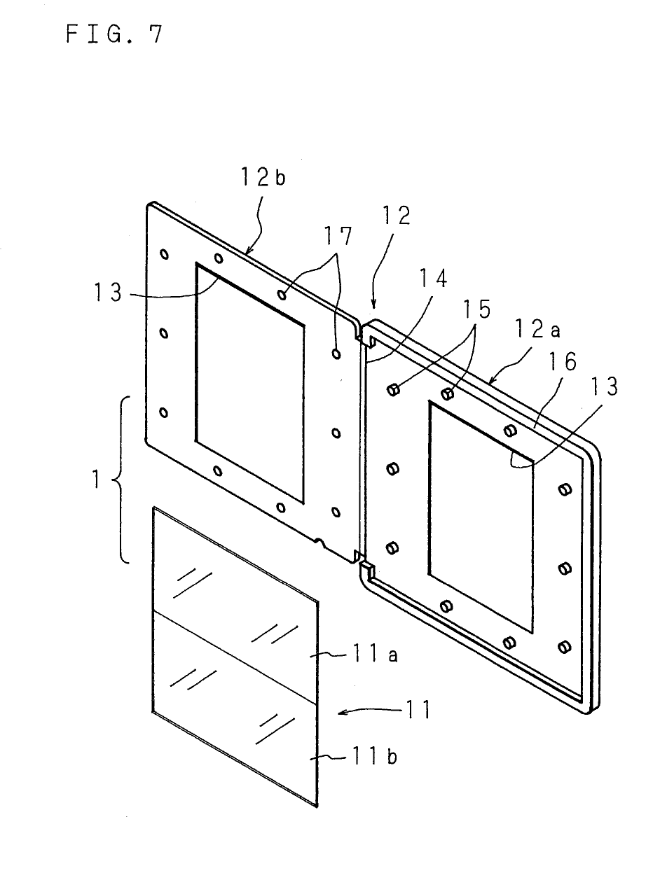

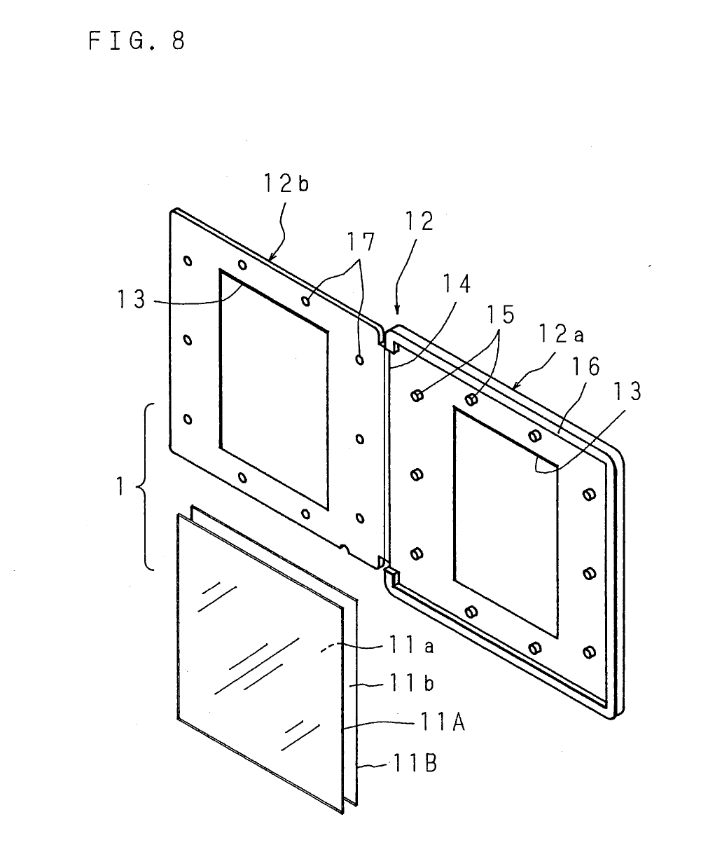

The above embodiment has used a plurality of attenuation filters 1. In place of using the plurality of attenuation filters 1, for example, as shown in FIG. 7, the filter main body 11 may be constructed in a manner that a plurality of attenuation portions 11a and 11b having different attenuation factors are arranged in parallel on its filter surface. Moreover, one filter main body 11 has been held in the retaining frame 12, and besides, as shown in FIG. 8, a plurality of filter main bodies 11A and 1B may be held in the holding frame in a state that their filter surfaces 11a and 11b face each other.

As this invention may be embodied in several forms without departing from the spirit of essential characteristics thereof, the present embodiment is therefore illustrative and not restrictive. Since the scope of the invention is defined by the appended claims rather than by the description preceding them, and all changes that fall within metes and bounds of the claims, or equivalence of such metes and bounds thereof are therefore intended to be embraced by the claims.

1. A sensitivity determining method for detecting sensitivity of an pre-existing optical sensor system, comprising the steps of:
selectively disposing an attenuation filter in a projected light area of a pre-existing optical sensor system, said optical sensor system including a light receiving unit which receives a light projected from a light projection unit within the projected light area, wherein said filter is separate and independent from said optical sensor system;
receiving light transmitted through the attenuation filter in the light receiving unit; and
determining sensitivity of the optical sensor system on the basis of the light received in the light receiving unit.

2. The method according to claim 1, wherein a plurality of attenuation filters having an equal or different transmittances are successively disposed in a projected light area of an existing optical sensor system, and each time the number of disposed said attenuation filters increases, sensitivity of the optical sensor system is determined on the basis of the light received in the light receiving unit.

3. The method according to claim 1, wherein a plurality of attenuation filters having different transmittances are successively disposed in a projected light area of said existing optical sensor system, and each time the disposed attenuation filter is replaced with a new one, sensitivity of the optical sensor system is determined on the basis of light received in the light receiving unit.

4. The method according to claim 1, wherein the attenuation filter is disposed in one or both of a projection side area ranging from the light projection unit to a reflection object and a reflection side area ranging from the reflection object to the light receiving unit, said light projection unit being provided integrally with the light receiving unit in the existing optical sensor.

5. The method according to claim 2, wherein each of the plurality of attenuation filters is disposed in one or both of a projection side area ranging from the light projection unit to a reflection object and a reflection side area ranging from the reflection object to the light receiving unit, said light projection unit being provided integrally with the light receiving unit in the existing optical sensor.

6. The method according to claim 3, wherein each of the plurality of attenuation filters is disposed in one or both of a projection side area ranging from the light projection unit to a reflection object and a reflection side area ranging from the reflection object to the light receiving unit, said light projection unit being provided integrally with the light receiving unit in the existing optical sensor.
